(19) United States
(12) Patent Application Publication
(10) Pub. No.: US 2026/0291080 A1
(43) Pub. Date: Sep. 24, 2026

(54) IN-SITU RADIO FREQUENCY CURRENT ASSESSMENT FOR ARRAY TRANSMISSION AND OPTIMIZATION

(71) Applicant: BAYLOR UNIVERSITY, Waco, TX (US)

(72) Inventors: Charles P. Baylis, II, Waco, TX (US); Adam Goad, Waco, TX (US); Austin Scott Egbert, Waco, TX (US)

(73) Assignee: BAYLOR UNIVERSITY, Waco, TX (US)

(21) Appl. No.: 19/475,103

(22) PCT Filed: Jun. 6, 2023
(86) PCT No.: PCT/US2023/024562

§ 371 Date: Oct. 14, 2025

(51) Int. Cl. H01Q 19/02; H03F 1/56; H03F 3/24; H04B 1/04

(52) U.S. Cl. CPC H01Q 19/025; H03F 1/56; H03F 3/245; H04B 1/0458; H03F 2200/451

(57) ABSTRACT

A system for array antenna, optimization, comprising a power amplifier, a tunable matching network coupled to the power amplifier, s 4-port coupler coupled to the tunable matching network, a phased array antenna coupled to the 4 port coupler and a software defined radio coupled to the 4-port coupler, wherein the tunable matching network is configured to modify an impedance as a. function of a plurality of voltages of the 4-port coupler.

### TECHNICAL FIELD

The present disclosure relates generally to wireless data transmission, and more specifically to an in-situ radio frequency (RF) current assessment for array transmission and optimization.

### BACKGROUND OF THE INVENTION

Phased-array transmitters can be useful, but due to congestion from other signal sources it is important to configure them properly. There are many problems with known approaches to configuring phased array transmitters.

### SUMMARY OF THE INVENTION

A system for array antenna optimization is disclosed that includes a power amplifier. A tunable matching network is connected to the power amplifier, and a 4-port coupler is coupled to the tunable matching network. A phased array antenna is connected to the 4 port coupler, and a software defined radio is connected to the 4-port coupler. The tunable matching network is configured to modify an impedance as a function of a plurality of voltages of the 4-port coupler.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings may be to scale, but emphasis is placed upon clearly illustrating the principles of the present disclosure. Moreover, in the drawings, like reference numerals designate corresponding parts throughout the several views, and in which:

FIG. 1 is a diagram of a system for configuring a phased-array antenna, in accordance with an example embodiment of the present disclosure;

FIG. 2 is a diagram of an algorithm for adjusting a matching network as a function of voltages measured at a 4-port coupler, in accordance with an example embodiment of the present disclosure;

FIG. 3 is a diagram of a validation model that uses an ideal dual-directional coupler;

FIG. 4 is a diagram of a measurement setup, in accordance with an example embodiment of the present disclosure;

FIG. 5 is a diagram of a schematic for a general case derivation, in accordance with an example embodiment of the present disclosure;

FIG. 6 is a diagram of measurements performed across different Γₐₙₜ values, resulting in varying values of vector antenna current Iₐₙₜ;

FIG. 7 is a diagram comparing measured and simulated voltages of both ports three and four of dual-directional coupler, in accordance with an example embodiment of the present disclosure;

FIG. 8 are diagrams of V₃ and V₄ in terms of the magnitudes and phase difference of the voltages for the different current magnitudes caused by the differing Γₐₙₜ values, in accordance with an example embodiment of the present disclosure;

FIG. 9 is a diagram comparing the antenna current Γₐₙₜ, based on the measurement of

$${V}_{3}^{-} and {V}_{4}^{-}$$

and the use of equations (11), (13), and (1) with the current value assessed directly in simulation using the current probe tool;

FIG. 10 is a diagram of error variation across the Γₐₙₜ Smith Chart using color coding, in accordance with an example embodiment of the present disclosure; and

FIG. 11 is a diagram of a comparison between measurement and simulation in terms of the current magnitude and phase values, in accordance with an example embodiment of the present disclosure.

### DETAILED DESCRIPTION OF THE INVENTION

In the description that follows, like parts are marked throughout the specification and drawings with the same reference numerals. The drawing figures may be to scale and certain components can be shown in generalized or schematic form and identified by commercial designations in the interest of clarity and conciseness.

In the increasingly congested wireless spectrum, phased-array transmitters can be used to provide spatial diversity as an additional measure of coexistence. Reconfigurable matching networks placed between the power-amplifier device and the antenna can allow the amplifiers in the transmitter elements to maximize output power while maintaining desired beam fidelity. A challenge with the use of reconfigurable matching networks in array transmitters is that they alter the system calibration. This disclosure provides a system and method for in-situ measurement evaluation of antenna input current using a dual-directional coupler placed in an array element. Measurement validation can be performed using a two-port vector network analyzer with an load-pull tuner emulating a changing antenna impedance, and after validation the system and method can be used in normal operation. The present disclosure improves the ability to maintain the array pattern and can ease issues stemming from changing array calibration with reconfigurable array element circuits.

Spectrum-use systems benefit from the ability to adapt to their surroundings and reconfigure to optimize performance in available spectral and spatial channels. In transmitter power amplifiers, an impedance tuner placed between the power amplifier device and antenna can provide on-the-fly impedance matching to maximize output power (and corresponding transmission range) or efficiency, while also minimizing nonlinearities that distort the spectrum and array pattern. Such real-time tunable behavior provides improved performance over wider bandwidths than is possible with a static transmitter design. When a reconfigurable impedance tuner is placed in an element of a transmitter array, reconfiguring the impedance tuner can cause the magnitude and phase of the element's transmission to change. If the impedances in different elements are tuned differently, that tuning can alter the array pattern. Because the surface current of the antenna determines the array pattern, it is desirable to monitor the antenna input current during impedance tuning to assess the effects of the tuning on the array transmission pattern. The present disclosure provides a measurement validation of this approach, and includes non-ideal measurement and measurement-port terminations.

Array transmitter calibration techniques can be used to assess the traveling-wave voltage magnitude and phase transmission parameters of each element using scattering parameters (S-parameters) or equivalent approaches. Calibration allows transmitter magnitude and phase offsets to be adjusted and allows receiver signal processing to be changed to ensure proper detection of the signal. If an uncorrected phase error exists, it can result in poor radar detection in radar arrays. In most array calibrations, external equipment or measurements are required.

Array calibration techniques can use internal calibration networks to determine drift from the initial calibration, but are not well adapted to accommodate drastic changes in transmission characteristic that result from adaptively changing power, frequency, and load impedance. While RF current measurements can be difficult to obtain, RF voltage measurements are simpler to perform. The present disclosure includes measurement validation of an approach to use two in-situ voltage measurements to calculate the total current present at the input to the antenna of each individual array element. With these real-time current measurements, array calibration is greatly simplified, since the antenna excitation can be known through changes in transmission characteristics, such as those induced by an impedance tuner, or varying mutual coupling environments.

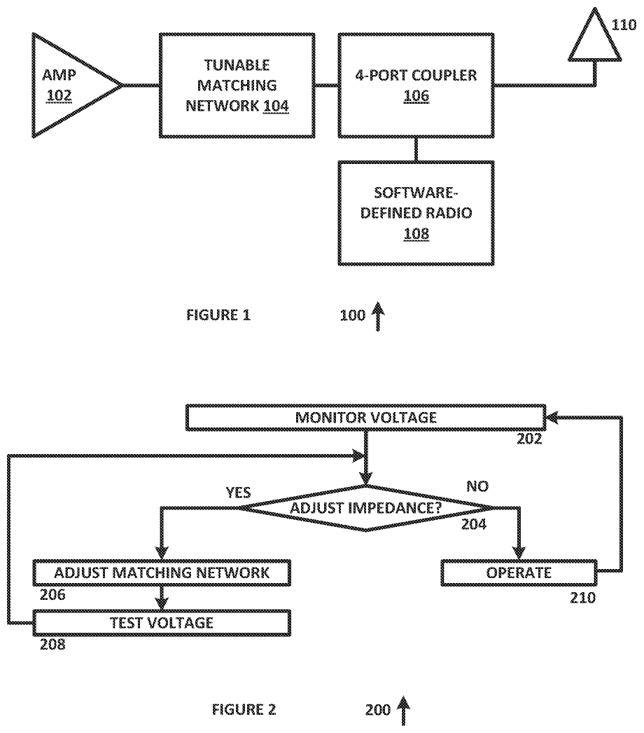

FIG. 1 is a diagram of a system 100 for configuring a phased-array antenna, in accordance with an example embodiment of the present disclosure. System 100 includes amplifier 102, tunable matching network 104, 4-port coupler 106, software-defined radio 108 and phased-array antenna 110.

Calculation of the current incident on phased array antenna 110 connected to the output port of 4-port coupler 106 can be performed using the following equations:

$${I}_{ant} = \frac{{V}_{ant}^{+} - {V}_{ant}^{-}}{{Z}_{0}} \qquad ( 1 )$$

$${V}_{ant}^{-} = \frac{{V}_{4}^{-} - \frac{{S}_{41}}{{S}_{31}} {V}_{3}^{-}}{{S}_{42} - \frac{{S}_{41} {S}_{32}}{{S}_{31}}} \qquad ( 2 )$$

$${V}_{ant}^{+} = \frac{{S}_{21}}{{S}_{31}} {V}_{3}^{-} + ( {S}_{22} - \frac{{S}_{21} {S}_{32}}{{S}_{31}} ) \frac{{V}_{4}^{-} - \frac{{S}_{41}}{{S}_{31}} {V}_{3}^{-}}{{S}_{42} - \frac{{S}_{41} {S}_{32}}{{S}_{31}}} \qquad ( 3 )$$

where
Iant is the current entering the antenna
Vant is the voltage across the antenna input ports
Zant is and the impedance seen looking into the antenna

While equation (1) is generally applicable, equations (2) and (3) are valid when

$${V}_{3}^{+} = {V}_{4}^{+} = 0.$$

This condition requires that perfect, non-reflecting loads be connected to ports 3 and 4 of 4-port coupler 106, which can be implemented as an RF-Lambda RFDDC8G2615 coupler or other suitable devices, and which may not have perfect, non-reflecting loads, depending on the measurement equipment used. As such, exact assessment of

$${V}_{ant}^{+} and {V}_{ant}^{-}$$

requires that these assumptions be removed. The following equations generically define the waves leaving the ports

$$( {V}_{1}^{-} , {V}_{2}^{-} , {V}_{3}^{-} , {V}_{4}^{-} )$$

in terms of the waves entering the ports

$$( {V}_{1}^{+} , {V}_{2}^{+} , {V}_{3}^{+} , {V}_{4}^{+} ) :$$

$${V}_{1}^{-} = {S}_{11} {V}_{1}^{+} + {S}_{12} {V}_{2}^{+} + {S}_{13} {V}_{3}^{+} + {S}_{14} {V}_{4}^{+} \qquad ( 4 )$$

$${V}_{2}^{-} = {S}_{21} {V}_{1}^{+} + {S}_{22} {V}_{2}^{+} + {S}_{23} {V}_{3}^{+} + {S}_{24} {V}_{4}^{+} \qquad ( 5 )$$

$${V}_{3}^{-} = {S}_{31} {V}_{1}^{+} + {S}_{32} {V}_{2}^{+} + {S}_{33} {V}_{3}^{+} + {S}_{34} {V}_{4}^{+} \qquad ( 6 )$$

$${V}_{4}^{-} = {S}_{41} {V}_{1}^{+} + {S}_{42} {V}_{2}^{+} + {S}_{43} {V}_{3}^{+} + {S}_{44} {V}_{4}^{+} \qquad ( 7 )$$

Additionally, if the loads on ports 3 and 4 possess known reflection coefficients Γ_{L3} and Γ_{L4}, respectively, then

$${V}_{3}^{+} = {Γ}_{L 3} {V}_{3}^{-} \qquad ( 8 )$$

$${V}_{4}^{+} = {Γ}_{L 4} {V}_{4}^{-} \qquad ( 9 )$$

Solving equation (6) for

$${V}_{1}^{+}$$

and using equations (8) and (9) gives

$${V}_{1}^{+} = \frac{1}{{S}_{31}} ( {V}_{3}^{-} - {S}_{32} {V}_{2}^{+} - {S}_{33} {Γ}_{L 3} {V}_{3}^{-} - {S}_{34} {Γ}_{L 4} {V}_{4}^{-} ) \qquad ( 10 )$$

Substituting equation (10) into equation (7), including use of equations (8) and (9), and solving for

$${V}_{2}^{+}$$

gives

$${V}_{2}^{+} = {V}_{ant}^{-} = \frac{\begin{matrix}{V}_{3}^{-} ( - \frac{{S}_{41}}{{S}_{31}} + \frac{{S}_{41} {S}_{33}}{{S}_{31}} {Γ}_{L 3} - {S}_{43} {Γ}_{L 3} ) + \\ {V}_{4}^{-} ( \frac{{S}_{41} {S}_{34}}{{S}_{31}} {Γ}_{L 4} - {S}_{44} {Γ}_{L 4} + 1 )\end{matrix}}{- \frac{{S}_{41} {S}_{32}}{{S}_{31}} + {S}_{42}} \qquad ( 11 )$$

Substituting equation (10) into equation (5) gives

$${V}_{2}^{-} = {V}_{ant}^{+} = {V}_{2}^{+} ( - \frac{{S}_{21} {S}_{32}}{{S}_{31}} + {S}_{22} ) + {V}_{3}^{-} ( \frac{{S}_{21}}{{S}_{31}} - \frac{{S}_{21} {S}_{33}}{{S}_{31}} {Γ}_{L 3} - {S}_{43} {Γ}_{L 3} ) + {V}_{4}^{-} ( - \frac{{S}_{21} {S}_{34}}{{S}_{31}} {Γ}_{L 4} + {S}_{24} {Γ}_{L 4} ) \qquad ( 12 )$$

Substituting equation (11) into equation (12) gives

$${V}_{2}^{-} = {V}_{ant}^{+} = {V}_{3}^{-} ( \frac{\frac{- {S}_{21} {S}_{32}}{{S}_{31}} + {S}_{22}}{\frac{- {S}_{41} {S}_{32}}{{S}_{31}} + {S}_{42}} ( - \frac{{S}_{41}}{{S}_{31}} + \frac{{S}_{41} {S}_{33}}{{S}_{31}} {Γ}_{L 3} - {S}_{43} {Γ}_{L 3} ) + ( \frac{{S}_{21}}{{S}_{31}} - \frac{{S}_{21} {S}_{33}}{{S}_{31}} {Γ}_{L 3} + {S}_{23} {Γ}_{L 3} ) ) + {V}_{4}^{-} ( \frac{\frac{- {S}_{21} {S}_{32}}{{S}_{31}} + {S}_{22}}{\frac{- {S}_{41} {S}_{32}}{{S}_{31}} + {S}_{42}} ( \frac{{S}_{41} {S}_{34}}{{S}_{31}} {Γ}_{L 4} - {S}_{44} {Γ}_{L 4} + 1 ) + ( - \frac{{S}_{21} {S}_{34}}{{S}_{31}} {Γ}_{L 4} + {S}_{24} {Γ}_{L 4} ) ) \qquad ( 13 )$$

The next step is to substitute

$${V}_{3}^{-} = {V}_{3} / ( 1 + {Γ}_{L 3} ) and {V}_{4}^{-} = {V}_{4} / ( 1 + {Γ}_{L 4} )$$

into equations (11) and (13) to obtain expressions for

$${V}_{ant}^{-} and {V}_{ant}^{+}$$

as follows:

$${V}_{2}^{+} = {V}_{ant}^{-} = \frac{\begin{matrix}\frac{{V}_{3}}{1 + {Γ}_{L 3}} ( - \frac{{S}_{41}}{{S}_{31}} + \frac{{S}_{41} {S}_{33}}{{S}_{31}} {Γ}_{L 3} - {S}_{43} {Γ}_{L 3} ) + \\ \frac{{V}_{4}}{1 + {Γ}_{L 4}} ( \frac{{S}_{41} {S}_{34}}{{S}_{31}} {Γ}_{L 4} - {S}_{44} {Γ}_{L 4} + 1 )\end{matrix}}{- \frac{{S}_{41} {S}_{32}}{{S}_{31}} + {S}_{42}} \qquad ( 14 )$$

$${V}_{2}^{-} = {V}_{ant}^{+} = \frac{{V}_{3}}{1 + {Γ}_{L 3}} ( \frac{\frac{- {S}_{21} {S}_{32}}{{S}_{31}} + {S}_{22}}{\frac{- {S}_{41} {S}_{32}}{{S}_{31}} + {S}_{42}} ( - \frac{{S}_{41}}{{S}_{31}} + \frac{{S}_{41} {S}_{33}}{{S}_{31}} {Γ}_{L 3} - {S}_{43} {Γ}_{L 3} ) + ( \frac{{S}_{21}}{{S}_{31}} - \frac{{S}_{21} {S}_{33}}{{S}_{31}} {Γ}_{L 3} + {S}_{23} {Γ}_{L 3} ) ) + \frac{{V}_{4}}{1 + {Γ}_{L 4}} ( \frac{\frac{- {S}_{21} {S}_{32}}{{S}_{31}} + {S}_{22}}{\frac{- {S}_{41} {S}_{32}}{{S}_{31}} + {S}_{42}} ( \frac{{S}_{41} {S}_{34}}{{S}_{31}} {Γ}_{L 4} - {S}_{44} {Γ}_{L 4} + 1 ) + ( - \frac{{S}_{21} {S}_{34}}{{S}_{31}} {Γ}_{L 4} + {S}_{24} {Γ}_{L 4} ) ) \qquad ( 15 )$$

This solution gives

$${V}_{ant}^{-} and {V}_{ant}^{+}$$

in terms of the total measured voltages V₃ and V₄. Unlike equations (2) and (3), equations (14) and (15) use total voltage measurements and account for the reflection from each port of the measurement device. This solution expands the measurement techniques that can be used to implement the disclosed systems and methods. For example, software-defined radio platform 108 (which measures total voltage and does not separate incident and reflected voltage waves) can be used in conjunction with an actual array platform to assess the total voltages V₃ and V₄, calculating

$${V}_{ant}^{-} and {V}_{ant}^{+}$$

using equations (14) and (15), respectively, and using these calculated voltages to assess the antenna current using equation (1).

Array calibration can include the characterization of the full transmit amplifier chain, such as where power amplifier 102 is a plurality of amplifiers, and often the antennas, channel, and receiver chain. However, the calibration is invalidated as the transmitter reconfigurable matching network is reconfigured. As such, array calibration techniques in a situation involving a reconfigurable matching network can require a pre-calibration for each possible matching network setting. Such pre-calibration is an involved task, due to the vast number of possible tuning configurations of the full array. Using direct monitoring of the antenna current as disclosed herein eliminates the need for pre-calibration, and if the antenna pattern is known, allows for monitoring of the array pattern in real-time. The disclosed current monitoring method only involves characterization of the passive four-port coupler and antenna, and thus provides novel and non-obvious advantages.

FIG. 2 is a diagram of an algorithm 200 for adjusting a matching network as a function of voltages measured at a 4-port coupler, in accordance with an example embodiment of the present disclosure. Algorithm 200 can be implemented in hardware or a suitable combination of hardware and software.

Algorithm 200 begins at 202, where a voltage is monitored at a 4-port network. In one example embodiment, the voltage can be measured using the systems and processes discussed herein or other suitable systems and processes can also or alternatively be used. The algorithm then proceeds to 204.

At 204, it is determined whether it is necessary to adjust an impedance, such as an impedance of a matching network or other suitable impedances for the compensation of the impedance of of a phased array antenna. The determination can be based on a solution to one or more of the algorithms disclosed and discussed herein or in other suitable manners. If it is determined that adjustment is needed, the algorithm proceeds to 206, otherwise the algorithm proceeds to 210 where the system is operated without modifying the impedance of the matching network.

At 206, a matching network impedance is adjusted to match the impedance of the phased array. In one example embodiment, the impedance can be adjusted using the systems and processes discussed herein or other suitable processes can also or alternatively be used. The algorithm then proceeds to 208.

At 208, the voltage across the 4-port coupler or other suitable devices is measured, and the algorithm returns to 204.

In operation, algorithm 200 can be used to adjust a matching network as a function of voltages measured at a 4-port coupler. While algorithm 200 is shown as a flow chart, a person of skill in the art will recognize that it can also or alternatively be implemented using a state diagram, using object-oriented programming, using a ladder diagram or in other suitable manners.

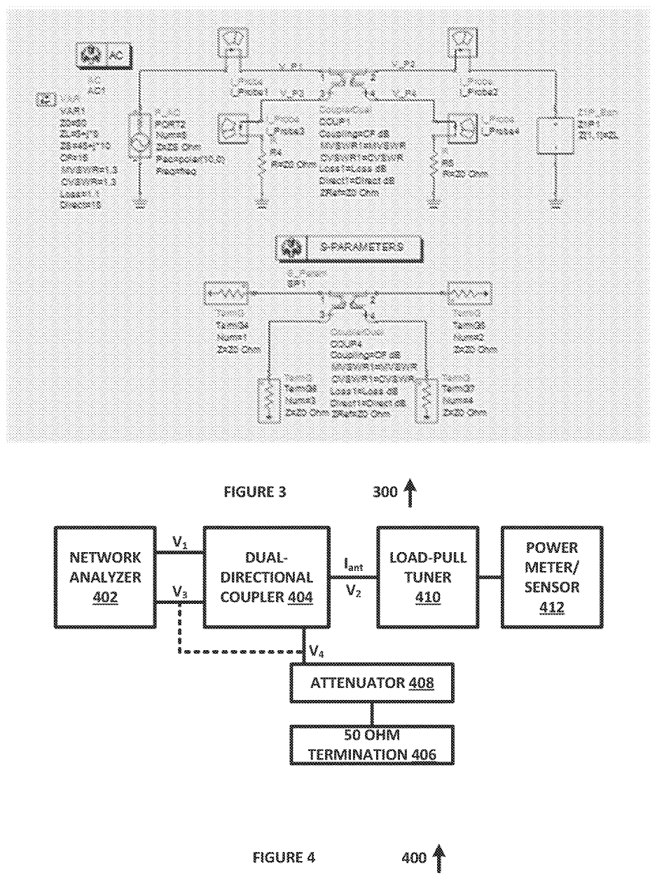

FIG. 3 is a diagram 300 of a validation model that uses an ideal dual-directional coupler. The present disclosure can be validated using the Keysight Advanced Design System (ADS) available from Keysight Technologies of Santa Rosa CA to perform simulations. Table I shows the results of an example simulation validation. Using the ADS,

$${V}_{3}^{-} and {V}_{4}^{-}$$

were assessed, and using equations (2) and (3) with (1) to calculate I_{calc}. The “ground truth” for comparison, Iₘₑₐₛ, is assessed through the ADS current probe tool (“I_Probe”) in diagram 300. Table I shows the results for this simulation with various source and load impedances using equations (2) and (3) with ideal 50Ω loads acting as the measurement device termination. These results demonstrate complete agreement between the simulated current and measured results

TABLE I
Simple Simulation Validation Test Results

| | Z_s | Z_L | V_3 | V_4 | I_meas | I_calc |
|---|---|---|---|---|---|---|
| # | (Ω) | (Ω) | (V) | (V) | (A) | (A) |
| 1 | 50 | 50 | 5.62/90° | 1.00/90° | 0.54/0° | 0.54/0° |
| 2 | 50 | 5 | 5.66/96° | 3.71/−74° | 0.89/0° | 0.89/0° |
| 3 | 50 | 5 + | 5.98/95° | 3.29/−105° | 0.87/−12° | 0.87/−12° |
| | | j15 | | | | |
| 4 | 15 | 50 | 4.43/90° | 0.787/0° | 0.43/0° | 0.43/0° |
| 5 | 15 + | 50 | 5.58/75° | 0.783/−6° | 0.43/−6° | 0.43/−6° |
| | j8 | | | | | |

FIG. 4 is a diagram of a measurement setup 400, in accordance with an example embodiment of the present disclosure. Measurement setup 400 includes network analyzer 402, dual-directional coupler 404, 50 ohm termination 406, attenuator 408, load-pull tuner 410 and power meter/sensor 412, each of which can be implemented in hardware or a suitable combination of hardware and software.

The present disclosure also validates the ability to assess the antenna currents with measured voltage waves. One port of network analyzer 402, which can be a vector network analyzer (VNA) or other suitable network analyzers, can be used to generate an incident voltage wave

$${V}_{1}^{+}$$

to port 1 of dual-directional coupler 404. A second port of network analyzer 402 can be used to sequentially measure the traveling-wave voltages

$${V}_{3}^{-} and {V}_{4}^{-}$$

based on the transmission measurement network analyzer 402 (giving S₃₁ and S₄₁). The measurements can be performed sequentially, such as when a two-port network analyzer is used for the measurement. The port not terminated in the second port of network analyzer 402 can be terminated in 50Ω load 406, and a 6 dB attenuator 408 can be used to remove unwanted reflections. Because network analyzer 402 is used to assess traveling-wave voltages, equations (11) and (13) can be used with the measured data to calculate

$${V}_{ant}^{-} and {V}_{ant}^{+}$$

for use in equation (1).

Because of the VNA calibration, along with the termination of the non-VNA connected port to the 6 dB attenuator and 50Ω load used during its characterization, it was assumed Γ_{L3}=Γ_{L4}=0 allowing use of (11) and (13).

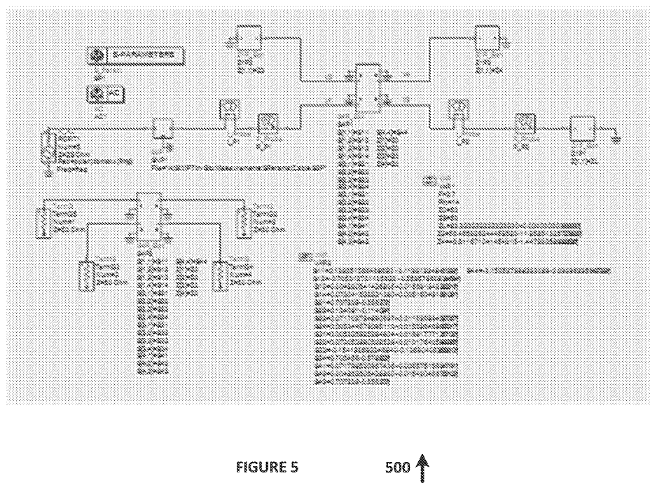

FIG. 5 is a diagram 500 of a schematic for a general case derivation, in accordance with an example embodiment of the present disclosure. This test used measured S-parameters of a coupler and allowed the ability to change not only the source and load impedances, but also the impedance of the measurement device(s) on the other two ports.

Several different impedances were connected to ports 3 and 4 of the coupler to test the disclosed analytical model. The results of these tests are shown in Table II. The currents I_{calc} shown in Table II, calculated using equations (1), (14), and (15), match the Iₘₑₐₛ results from the ADS current probe in all cases to floating-point precision. This simulation demonstrates the applicability of the present disclosure to measurement equipment using the more complete calculations prescribed in equations (1), (14), and (15). As expected, the results correlate exactly in an environment free from measurement noise and repeatability issues.

TABLE II
Advanced Simulation Validation Test Results

| | Z_s | Z_L | Z_3 | Z_4 | I_meas | I_calc |
|---|---|---|---|---|---|---|
| # | (Ω) | (Ω) | (Ω) | (Ω) | (A) | (A) |
| 1 | 50 | 50 | 50 | 50 | 0.54/−59.30° | 0.54/−59.30° |
| 2 | 50 | 5 | 15 | 35 | 0.98/−59.69° | 0.98/−59.69° |
| 3 | 50 | 5 + | 15 + | 35 + | 0.94/−74.96° | 0.94/−74.96° |
| | | j15 | j25 | j5 | | |
| 4 | 15 | 50 | 15 + | 155 | 0.45/−59.30° | 0.45/−59.30° |
| | | | j25 | | | |
| 5 | 15 + | 50 | 250 | 155 + | 0.45/−66.29° | 0.45/−66.29° |
| | j8 | | | j30 | | |

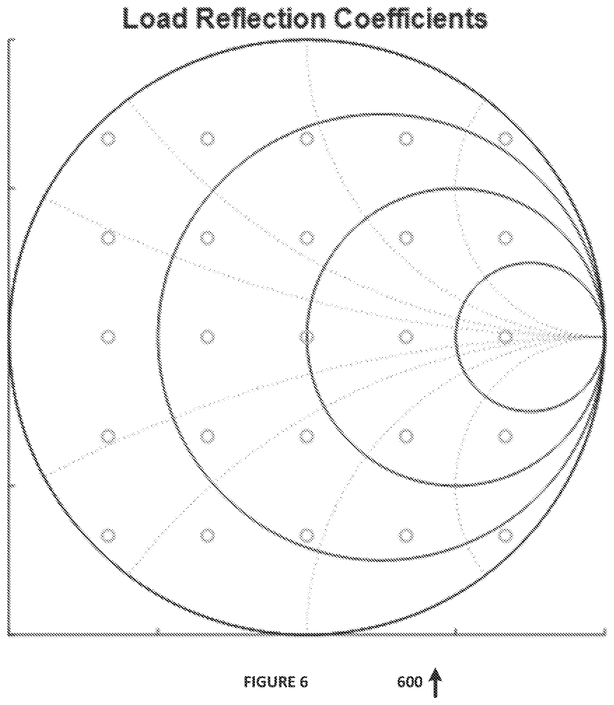

FIG. 6 is a diagram 600 of measurements performed across different Γₐₙₜ values, resulting in varying values of vector antenna current Iₐₙₜ. For comparison, calculation of current for the same 25 points was performed in the ADS. In both simulation and measurement, V₃ was chosen as the phase reference of zero degrees. Diagram 600 shows emulated values of the antenna reflection coefficient Γₐₙₜ using a load-pull tuner.

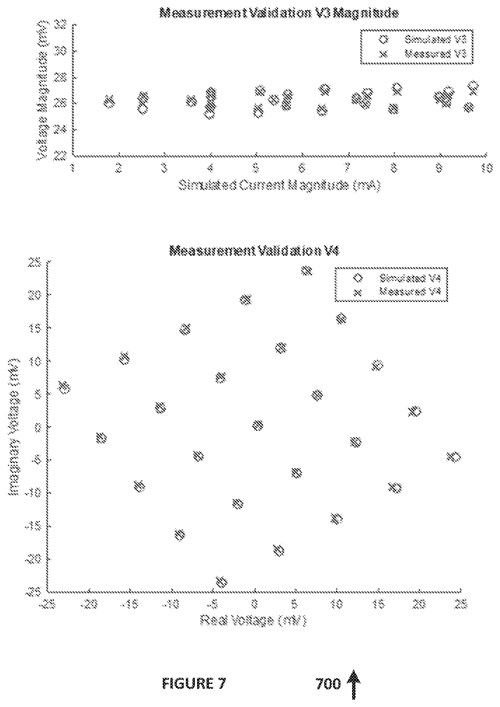

FIG. 7 is a diagram 700 comparing measured and simulated voltages of both ports three and four of dual-directional coupler 404, in accordance with an example embodiment of the present disclosure. A comparison of the voltage measurements against a simulation is shown for (a) V_3 and (b) V_4. The voltage for V_3 is used as the zero phase reference; as such, only magnitude is shown. When compared with the simulation results using the same input voltage and the characterized-network S-parameters, the magnitudes of V₃ have a maximum percent error of 1.72% and an average error magnitude of 179.49 V. The values for V₄ have a maximum percent error of 25.98%, but this error occurs at the point where the load was set to 50Ω, and the magnitude of V₄ is near zero. The actual voltage error magnitude is only 108.11 V, and the average voltage error magnitude is 330.12 V.

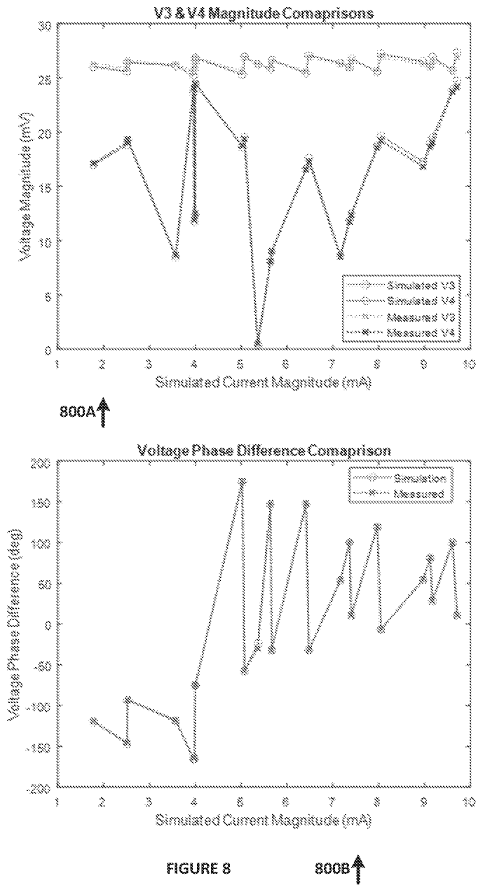

FIG. 8 are diagrams 800A and 800B of V₃ and V₄ in terms of the magnitudes and phase difference of the voltages for the different current magnitudes caused by the differing Γₐₙₜ values, in accordance with an example embodiment of the present disclosure. The comparison of V_3 and V_4 for the measured and simulated voltage 800A magnitude and 800B phase difference are shown. The simulated and measured values appear nearly identical. Diagram 800A shows that the measured voltage magnitudes of V₃ and V₄ compare very well to the simulated data. Diagram 800B shows excellent agreement between the measured and simulated phase differences between the voltages.

The strong agreement between these simulations and measurements demonstrates accurate modeling of the test setup in the simulator. This means that it is expected that the measured and simulated values of Iₐₙₜ will also have good correspondence.

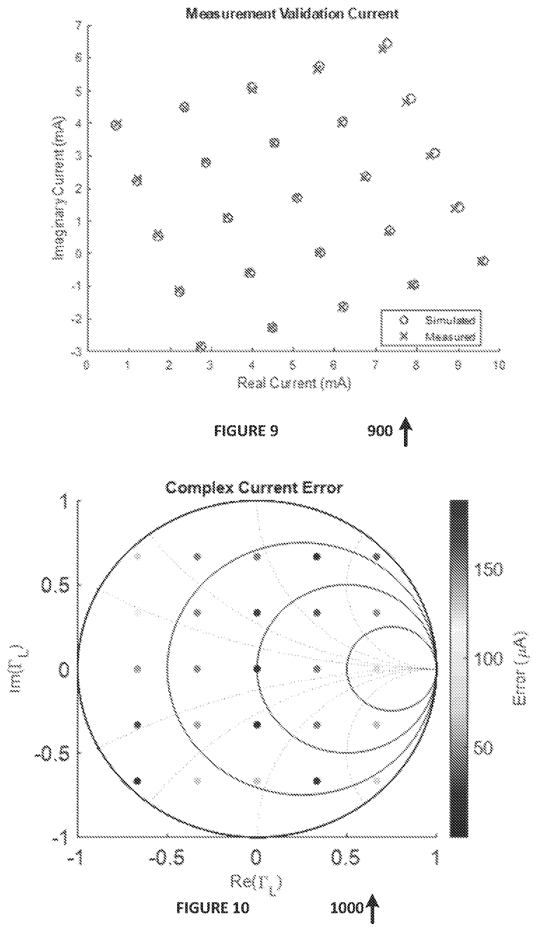

FIG. 9 is a diagram 900 comparing the antenna current Iₐₙₜ, based on the measurement of

$${V}_{3}^{-} and {V}_{4}^{-}$$

and the use of equations (11), (13), and (1) with the current value assessed directly in simulation using the current probe tool. The measured current values have an average error magnitude of 66.87 μA and average percent error of 1.23%. The maximum current error magnitude was 187.93 μA, with a maximum percent error of 4.42% observed. The comparison shows measured and simulated currents for all points on the complex plane.

FIG. 10 is a diagram 1000 of error variation across the Γₐₙₜ Smith Chart using color coding, in accordance with an example embodiment of the present disclosure. The measured versus simulated current error vector magnitude is shown as a function of Γ_ant. The error generally increases at larger reflection magnitudes, as the reflected signal at coupler port 4 becomes more pronounced, and its phase accuracy plays a more significant role in the result. Many of the points near the left edge of the Smith Chart have the highest error vector magnitude currents. However, it should be noted that the real part of the impedance is very low in this region, resulting in large currents. While the error is larger in value, it is a smaller fraction of the actual current for these values of Γₐₙₜ. The impedance with the maximum error in diagram 1000 has a percent error of only 1.93% (this is a 187 μA error vector magnitude for a 9.71 mA measurement).

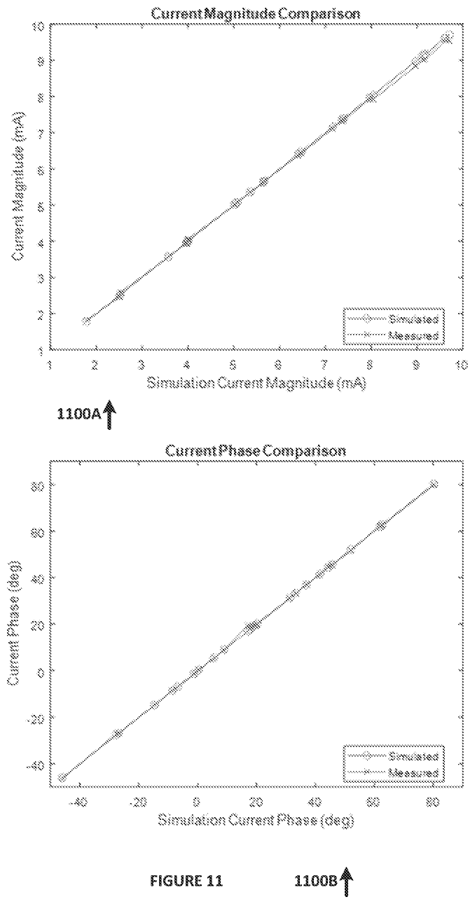

FIG. 11 are diagrams showing a comparison between measurement 1100A and simulation 1100B in terms of the current magnitude and phase values, in accordance with an example embodiment of the present disclosure. Since the plot of measurement and simulation data is performed against simulated data, the simulated data forms a straight line on the plot, and the variation of the measured data from this line can be observed. In this visualization, it is also apparent that current calculations from measurement results correspond very well to the simulated current-probe data.

A method of monitoring the current entering a phased-array antenna has been measurement validated using traveling-wave voltage measurements with a four-port dual-directional coupler. Further, a measurement approach allowing the total voltage at the coupled ports has been derived and validated through extended simulation results. This disclosure can be utilized for in-situ implementation in array transmitter elements, and can be useful when element transmission magnitude and phase are expected to vary in real-time, such as when real-time impedance tuning is performed in the element, or mutual coupling changes antenna impedance (such as when mutual coupling varies from element to element). The ability to monitor the input current to the array antennas allows calculation of the array transmit pattern if the individual antenna patterns are predetermined, which removes the need for pre-calibration of the transmitter at all possible tuner settings. Further, the disclosed system and method can be used to replace or to provide useful assistance to traditional array calibration for some applications. When implemented in an array setup, the present disclosure can enable the use and reconfiguration of tunable matching networks to optimize array performance with changing transmission characteristics in a dynamic environment. The theoretical, simulation, and measurement-based justification of the in-situ monitoring approach presented in this disclosure can be used in transmitters with confidence that it will provide accurate monitoring of the antenna currents.

As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. As used herein, phrases such as “between X and Y” and “between about X and Y” should be interpreted to include X and Y. As used herein, phrases such as “between about X and Y” mean “between about X and about Y.” As used herein, phrases such as “from about X to Y” mean “from about X to about Y.”

As used herein, “hardware” can include a combination of discrete components, an integrated circuit, an application-specific integrated circuit, a field programmable gate array, or other suitable hardware. As used herein, “software” can include one or more objects, agents, threads, lines of code, subroutines, separate software applications, two or more lines of code or other suitable software structures operating in two or more software applications, on one or more processors (where a processor includes one or more microcomputers or other suitable data processing units, memory devices, input-output devices, displays, data input devices such as a keyboard or a mouse, peripherals such as printers and speakers, associated drivers, control cards, power sources, network devices, docking station devices, or other suitable devices operating under control of software systems in conjunction with the processor or other devices), or other suitable software structures. In one exemplary embodiment, software can include one or more lines of code or other suitable software structures operating in a general purpose software application, such as an operating system, and one or more lines of code or other suitable software structures operating in a specific purpose software application. As used herein, the term “couple” and its cognate terms, such as “couples” and “coupled,” can include a physical connection (such as a copper conductor), a virtual connection (such as through randomly assigned memory locations of a data memory device), a logical connection (such as through logical gates of a semiconducting device), other suitable connections, or a suitable combination of such connections. The term “data” can refer to a suitable structure for using, conveying or storing data, such as a data field, a data buffer, a data message having the data value and sender/receiver address data, a control message having the data value and one or more operators that cause the receiving system or component to perform a function using the data, or other suitable hardware or software components for the electronic processing of data.

In general, a software system is a system that operates on a processor to perform predetermined functions in response to predetermined data fields. A software system is typically created as an algorithmic source code by a human programmer, and the source code algorithm is then compiled into a machine language algorithm with the source code algorithm functions, and linked to the specific input/output devices, dynamic link libraries and other specific hardware and software components of a processor, which converts the processor from a general purpose processor into a specific purpose processor. This well-known process for implementing an algorithm using a processor should require no explanation for one of even rudimentary skill in the art. For example, a system can be defined by the function it performs and the data fields that it performs the function on. As used herein, a NAME system, where NAME is typically the name of the general function that is performed by the system, refers to a software system that is configured to operate on a processor and to perform the disclosed function on the disclosed data fields. A system can receive one or more data inputs, such as data fields, user-entered data, control data in response to a user prompt or other suitable data, and can determine an action to take based on an algorithm, such as to proceed to a next algorithmic step if data is received, to repeat a prompt if data is not received, to perform a mathematical operation on two data fields, to sort or display data fields or to perform other suitable well-known algorithmic functions. Unless a specific algorithm is disclosed, then any suitable algorithm that would be known to one of skill in the art for performing the function using the associated data fields is contemplated as falling within the scope of the disclosure. For example, a message system that generates a message that includes a sender address field, a recipient address field and a message field would encompass software operating on a processor that can obtain the sender address field, recipient address field and message field from a suitable system or device of the processor, such as a buffer device or buffer system, can assemble the sender address field, recipient address field and message field into a suitable electronic message format (such as an electronic mail message, a TCP/IP message or any other suitable message format that has a sender address field, a recipient address field and message field), and can transmit the electronic message using electronic messaging systems and devices of the processor over a communications medium, such as a network. One of ordinary skill in the art would be able to provide the specific coding for a specific application based on the foregoing disclosure, which is intended to set forth exemplary embodiments of the present disclosure, and not to provide a tutorial for someone having less than ordinary skill in the art, such as someone who is unfamiliar with programming or processors in a suitable programming language. A specific algorithm for performing a function can be provided in a flow chart form or in other suitable formats, where the data fields and associated functions can be set forth in an exemplary order of operations, where the order can be rearranged as suitable and is not intended to be limiting unless explicitly stated to be limiting.

It should be emphasized that the above-described embodiments are merely examples of possible implementations. Many variations and modifications may be made to the above-described embodiments without departing from the principles of the present disclosure. All such modifications and variations are intended to be included herein within the scope of this disclosure and protected by the following claims.

What is claimed is:

1. A system for array antenna optimization, comprising:
a power amplifier;
a tunable matching network coupled to the power amplifier;
a 4-port coupler coupled to the tunable matching network;
a phased array antenna coupled to the 4 port coupler; and
a software defined radio coupled to the 4-port coupler, wherein the tunable matching network is configured to modify an impedance as a function of a plurality of voltages of the 4-port coupler.

2. The system of claim 1 wherein the impedance of the tunable matching network is modified automatically.

3. The system of claim 1 wherein the 4-port coupler is an RF-Lambda RFDDC826G15 coupler.

4. The system of claim 1 wherein the 4-port coupler is a dual-directional coupler.

5. The system of claim 1 wherein the 4-port coupler is coupled to an attenuator.

6. The system of claim 1 wherein the 4-port coupler is coupled to an attenuator and the attenuator is coupled to a 50 ohm termination.

7. The system of claim 1 wherein the 4-port coupler is coupled to a load-pull tuner.

8. The system of claim 1 wherein the tunable matching network comprises a network analyzer.

9. The system of claim 1 wherein the tunable matching network comprises a vector network analyzer.

10. The system of claim 1 wherein the power amplifier comprise a plurality of amplifiers.

11. A method for optimizing a system containing an antenna, comprising:
measuring a plurality of voltages at a 4-port coupler that is coupled to a tunable matching network, a phased array antenna and a software-defined radio;
determining an impedance value for the tunable matching network; and
adjusting an impedance of the tunable matching network to match the impedance value.

12. The method of claim 11 wherein determining the impedance value for the tunable matching network is performed automatically.

13. The method of claim 11 wherein the 4-port coupler is an RF-Lambda RFDDC826G15 coupler.

14. The method of claim 11 wherein the 4-port coupler is a dual-directional coupler.

15. The method of claim 11 wherein the 4-port coupler is coupled to an attenuator.

16. The method of claim 11 wherein the 4-port coupler is coupled to an attenuator and the attenuator is coupled to a 50 ohm termination.

17. The method of claim 11 wherein the 4-port coupler is coupled to a load-pull tuner.

18. The method of claim 11 wherein the tunable matching network comprises a network analyzer.

19. The method of claim 11 wherein the tunable matching network comprises a vector network analyzer.

20. The method of claim 11 wherein the power amplifier comprise a plurality of amplifiers.
